(19) United States
(12) Patent Application Publication
(10) Pub. No.: US 2026/0287641 A1
(43) Pub. Date: Sep. 24, 2026

(54) METHOD FOR ESTIMATING THE LEVEL OF DAMAGE TO AN ELEMENT OF AN ASSEMBLY, AND PREDICTIVE MAINTENANCE METHOD IMPLEMENTED ON THE BASIS OF SUCH AN ESTIMATION METHOD

(71) Applicant: SAFRAN ELECTRONICS & DEFENSE, Paris (FR)

(72) Inventors: Denis LECORDIER, Moissy-Cramayel (FR); Philippe CHOCTEAU, Moissy-Cramayel (FR); Richard LUCAS, Moissy-Cramayel (FR); Lucas ROUX, Moissy-Cramayel (FR); Mateo BECQUART, Moissy-Cramayel (FR)

(21) Appl. No.: 19/568,359

(22) Filed: Mar. 16, 2026

(30) Foreign Application Priority Data
Mar. 20, 2025 (FR) FR2502851

(51) Int. Cl. G01R 31/28; G01L 1/22; H05K 3/00

(52) U.S. Cl. CPC G01R 31/281; G01L 1/2262; H05K 3/00; H05K 2203/16

(57) ABSTRACT

A method for estimating the level of damage to an element of an assembly of an electronic component to an electronic board, of an electronic component to an electronic board including a printed circuit board and at least one gasket having viscoplastic behavior made between the printed circuit board and the electronic component, the method including the following steps: supplying the assembly, voluntarily or involuntarily exerting an external stress (γₑₓₜ), repeated and variable over time, on the electronic board so as to generate a change in the viscoplastic behavior of the gasket, estimating a time constant (τ) of an electrical quantity of the electronic component or of an internal component of the electronic board located inside the printed circuit board and facing the gasket between two instants (t₀, t₁) during the viscoplastic deformation of the gasket, estimating a level of damage to the element from the estimated time constant (τ).

### TECHNICAL FIELD OF THE INVENTION

The invention relates to the technical field of the methods for estimating the level of damage to an element of an assembly. The invention also relates to a predictive maintenance method based on such an estimation method.

The invention is used in particular to monitor the progress of damage to an element of an electronic board assembly during ageing or robustness tests, and to monitor evolution in the level of damage to an on-board electronic board.

### TECHNICAL BACKGROUND

The manufacturers have tried to estimate the level of damage to a part using non-destructive methods, but have been unable to deploy them on a large scale due to their high cost, complexity of use, inability to detect cracks or lack of compatibility with the parts and/or components to be analyzed.

Alternatively, it has also been proposed to estimate the level of damage using metallographic sections. However, it is not possible to repeat a test with a cut sample, so the only option is to use several cut samples at regular intervals. This solution is not entirely satisfactory, as it raises the problem of dispersion between the samples. As a result, it is necessary to cut several samples at different instants during the service life of the component or of the part in order to be accurate, which is time-consuming and costly.

We have also tried to estimate the level of damage to a gasket on an electronic board, although this is not well documented. Whether manufactured by brazing or welding, the gaskets are generally made from a material that exhibits both a viscoplastic behavior and electrical properties that vary according to the mechanical or thermomechanical stresses to which they are subjected. It was therefore proposed to estimate the level of damage to such gaskets by analyzing evolutions in their electrical resistance.

It has been proposed to estimate the level of cracking of a gasket by analyzing the evolution of the electrical resistance of said gasket. It was found that the electrical resistance only starts to vary when the level of cracking is 10% and increases linearly when the level of cracking evolves between 20% and 80%. The electrical resistance only increases significantly when the level of cracking reaches 80%.

Thus, taking the example of a gasket with an electrical resistance substantially equal to 1 μΩ before any cracking and assuming, optimistically, that a 10 μm crack occurs in this gasket, it is possible to calculate the evolution of the electrical resistance of this gasket according to the evolution of the cracking. At 25% cracking, the electrical resistance is approximately 1.5 μΩ. At 50% cracking, the electrical resistance is approximately 2 μΩ. When cracking is at 75%, the electrical resistance is substantially equal to 4 μΩ and when cracking is at 99%, the electrical resistance is substantially equal to 100 μΩ. This shows that the electrical resistance only varies from 1 μΩ to 2 μΩ when cracking increases from 25% to 75%.

These variations in electrical resistance are very small and do not allow the level of cracking to be monitored with any certainty without the use of a very precise and expensive measuring tool. This is all the more critical in on-board environments, since the internal resistors of the components is two orders of quantities greater than that measured on gaskets. Furthermore, it is only when the cracking is almost complete, i.e., when it is close to 100%, that the electrical resistance increases significantly to reach 100 μΩ, i.e., an increase of 2500% between 75% cracking and 99% cracking. In practice, therefore, it is not possible to know how far the cracking has progressed until it is almost complete, if at all.

In such conditions, it is therefore not possible to take preventive action such as maintenance to avoid the failure of the electronic board and the apparatus wherein this card is placed. When an electronic apparatus fails, the end user is affected in operational terms, as the apparatus is likely to be immobilized at an undesired instant in order to first identify the cause or causes of the failure and then perform the necessary maintenance. Moreover, once the failure has occurred, it may have undesirable side-effects.

In certain rare cases, a preventive maintenance, such as reconditioning, may be proposed after a certain number of hours of operation or cycles of use. However, this criterion is not very precise, so end users generally do not want to carry out preventive maintenance.

The document FR3096140A1 discloses a method for estimating the level of damage to an element of an assembly.

The invention aims to overcome at least some of the aforementioned problems and, in this respect, proposes a method for estimating the level of damage to an element of an assembly which allows to monitor the evolution of damage over the entire dynamic range of damage, thus allowing to prevent damage before it is complete and to characterize this damage.

### SUMMARY OF THE INVENTION

To this end, the invention proposes a method for estimating the level of damage to an element of an assembly, the assembly comprising:
an electronic component,
an electronic board comprising a printed circuit board, and
at least one gasket having viscoplastic behavior made between the printed circuit board and the electronic component,
the estimation method comprising the following steps:
supplying the assembly,
voluntarily or involuntarily exerting an external stress, repeated and variable over time, on the electronic board so as to generate a change in the viscoplastic behavior of the gasket,
estimating a time constant of an electrical quantity of the electronic component or of an internal component of the electronic board located inside the printed circuit board and opposite the gasket between two instants during the modification of the viscoplastic behavior of the gasket,
estimating the level of damage to the element of the assembly from the previously estimated time constant.

The method according to the invention overcomes the aforementioned disadvantages of the prior art. According to the invention, the level of damage is estimated by first estimating the time constant of the electrical quantity of the electronic component or of the internal component of the electronic board between two instants. Unlike the prior art, the method according to the invention does not directly measure an electrical property of the gasket or of any other element of the assembly, but rather the time constant of the electrical quantity of the electronic component.

By estimating the time constant of the electrical quantity of the component, we may determine the evolution dynamic of the measured electrical quantity, which accounts for changes in the dimensions of the electronic component as a result of the relaxation of the external stress by the gasket during the modification of the viscoplastic behavior of the gasket. Indeed, when the element of the assembly undergoes a damage, this necessarily results in a change in the viscoplastic behavior of the gasket, even if the gasket itself is not necessarily damaged. This change in the viscoplastic behavior of the gasket may be due to a reduction in the stiffness or viscosity of the gasket. The invention therefore exploits the viscoplastic behavior of the gasket when subjected to a repeated and time-varying external stress to estimate the level of damage to the element of the assembly.

By estimating the time constant, it is possible not only to identify a change in the state of the element of the assembly, and therefore damage to it, but also to determine precisely the instants at which these changes in state occurred and their degree of impact. As a result, the level of damage may be estimated continuously over the entire range of possible changes.

According to various characteristics of the invention which may be taken together or separately:
the method comprises, concomitantly with the step of exerting an external stress, a step consisting of determining an evolution in the external stress and/or an amplitude of a variation in the external stress during the exertion of the external stress and the modification of the viscoplastic behavior of the gasket;
the step of estimating the level of damage to the element of the assembly comprises:
   recording the evolution of the time constant as a function of the evolution of the external stress and/or the amplitude of the variation of the external stress between two instants during the modification of the viscoplastic behavior of the gasket,
   analyzing the evolution in the time constant between the two instants,
   estimating the level of damage to the element of the assembly;
the step of estimating the level of damage to the element of the assembly comprises the following sub-steps:
   supplying an abacus representing the evolution of the time constant as a function of the duration and/or frequency of exertion and/or the amplitude of the variation in the external stress, or supplying a database comprising predetermined values of the time constant as a function of the duration and/or frequency of exertion and/or the amplitude of the external stress,
   comparing the time constant with data from the abacus or from the database,
   estimating the level of damage to the element;
the electrical quantity of the electronic component varies as a function of the external stress, and wherein, during the estimation step, the time constant of the electrical quantity of the electronic component is estimated;
the method further comprises, before the step of estimating the time constant, the following steps:
   measuring the electrical quantity of the electronic component,
   treating the measurements made during the measurement step;
the electronic component is a Wheatstone bridge, each resistor of which is connected to the printed circuit board by a gasket having viscoplastic behavior, and the electrical quantity is an output voltage of the Wheatstone bridge;
the electronic component is a resistor, and wherein the electrical quantity is the resistance of the electronic component;
the resistor is a metal foil resistor;
the gasket is made of an alloy selected from Sn63Pb37, le Sn62Pb36Ag2, SAC305, SAC105, SAC387, Sn100C, etc. ;
the electrical quantity of the electronic component is independent of the external stress, and wherein, during the step of estimating the time constant, the time constant of the internal component of the electronic board is estimated;
the internal component is a resistor;
the internal component is made of constantan;
the electronic component is a capacitor, and wherein the electrical quantity is the capacitance of the electronic component;
the electronic component is an inductor, and wherein the electrical quantity is the inductance of the electronic component;
the external stress is a temperature variation, a tension, a compression, a bending, a torsion, a rotational speed of a rotating turbomachine part or an acceleration;
the element of the assembly is a body of the electronic component, a tab for attaching the electronic component to the printed circuit board, the gasket or a soldering pad interposed between the gasket and the printed circuit board.

The invention also relates to a method for monitoring the evolution of damage comprising the following steps:
implementing a method for estimating the level of damage to an element of an assembly as previously described,
successively repeating the step of estimating the time constant and the step of estimating the level of damage to the element several times during the modification of the viscoplastic behavior of the gasket.

The invention also relates to a method for maintaining predictively an electronic board comprising the following steps:
implementing a method for estimating the level of damage to an element of an assembly as previously described or a monitoring method as previously described,
carrying out a preventive maintenance on the electronic board according to the level of damage estimated at the end of the estimation step or a last estimation step.

### BRIEF DESCRIPTION OF THE FIGURES

Further objects, characteristics and advantages of the invention will become clearer in the following description, made with reference to the attached figures, wherein:

FIG. 1 is a schematic view illustrating the various steps of a damage estimation method according to one embodiment of the present invention;

FIG. 2a schematically illustrates an example of an electronic board comprising a gasket having viscoplastic behavior, to which a damage estimation method according to the invention may be applied;

FIG. 2b provides a schematic illustration of the electronic board shown in FIG. 2a after cracking at the level of a gasket between a printed circuit board and an electronic component;

FIG. 2c schematically illustrates the electronic board of FIG. 2a after cracking at the level of a connection area of the printed circuit board connected to the gasket;

FIG. 3 schematically illustrates another example of an electronic board comprising a gasket having viscoplastic behavior;

FIG. 4 is a schematic representation of the viscosity of the elements of an electronic board as used in the method according to the invention before a cracking in the gasket (new gasket);

FIG. 5 is a schematic representation of the viscosity of the elements of an electronic board as used in the method according to the invention during a cracking of the gasket (cracked gasket);

FIG. 6 is a schematic representation of the overall viscosity of the elements of an electronic board as used in the method according to the invention before a cracking of the gaskets;

FIG. 7 is an overall schematic representation of the viscosity of the elements of an electronic board as used in the method according to the invention during a cracking of the gaskets;

FIG. 8 is a schematic representation of the viscosity of the elements of an electronic board as used in the method according to the invention: when the gasket and the connection area of the printed circuit board are new (A), when only the gasket is cracked (B), when only the connection area of the printed circuit board is cracked (C);

FIG. 9a schematically illustrates the measurement of an output voltage when the electronic component is a Wheatstone bridge according to a first case of application of a first embodiment of the method according to the invention;

FIG. 9b shows a Wheatstone bridge resistor network;

FIG. 10 schematically illustrates the measurement of a resistor when the electronic component is a resistor according to a second case of application of a first embodiment of the method according to the invention;

FIG. 11 illustrates the evolution of a time constant of a resistor as measured in FIG. 10;

FIG. 12 illustrates the evolution of the resistance as a function of time for a resistor before the cracking of the gasket (new gasket);

FIG. 13 illustrates the evolution of the resistance as a function of time for a resistor during the cracking of the gasket (cracked gasket);

FIG. 14 schematically illustrates an assembly used to implement a second embodiment of the invention;

FIG. 15 is a schematic view illustrating the various steps of a method for monitoring the evolution of a damage according to one embodiment of the present invention;

FIG. 16 is a schematic view illustrating the various steps of a predictive maintenance method for an electronic board according to one embodiment of the present invention.

In the figures shown, optional steps are indicated by dotted boxes.

### DETAILED DESCRIPTION OF THE INVENTION

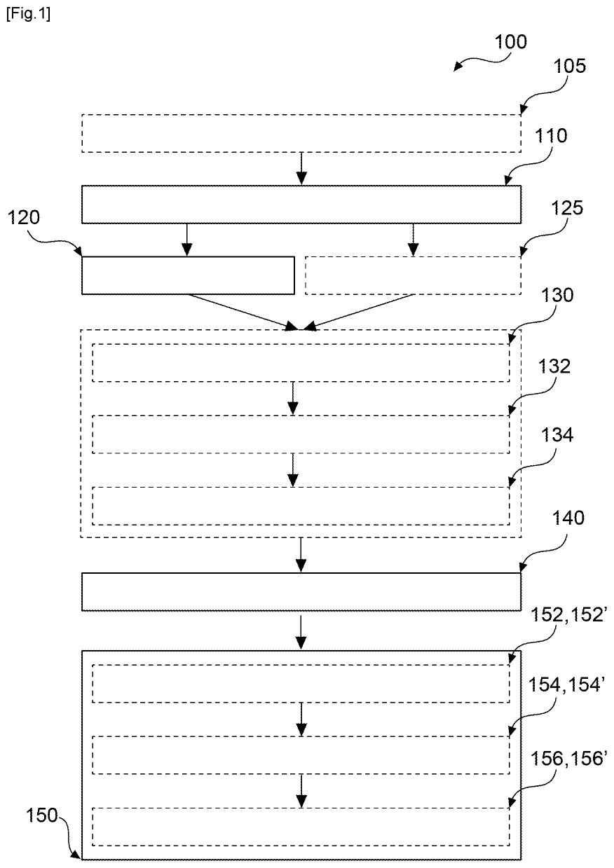

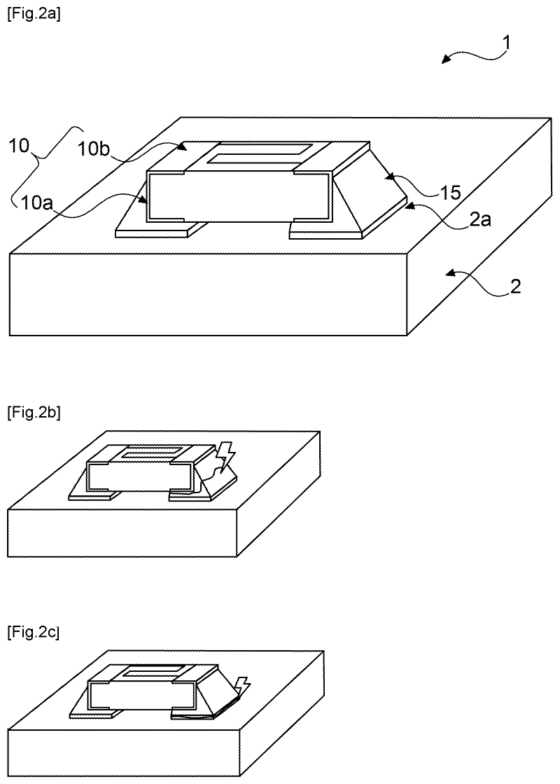

With reference to FIGS. 1 and 2a, the invention relates to a method 100 for estimating the level of damage to an element of an assembly. The assembly comprises an electronic component 10, an electronic board 1 typically comprising a Printed Circuit Board (PCB) 2 and at least one gasket 15 having viscoplastic behavior made between the printed circuit board 2 and the electronic component 10. More specifically, the electronic component 10 is assembled on the surface of the printed circuit board 2 by at least one gasket 15 having viscoplastic behavior. In the example shown in FIG. 2a, there are two such gaskets 15.

It should be noted that most of the gaskets 15 found in the electronic boards 1 are made from an alloy selected from Sn63Pb37, Sn62Pb36Ag2, SAC305, SAC105, SAC387, Sn100C, etc. and therefore naturally has a viscoplastic behavior.

When subjected to a repeated stress that varies over time, the viscoplastic behavior of the gasket 15 changes. This change in the viscoplastic behavior of the gasket 15 may result in the gasket 15 deforming inelastically, i.e., plastically, or it may not result in the gasket 15 deforming and sustaining a damage. In this way, an element of the assembly (which is not the gasket 15) may be damaged before the gasket 15 itself is deformed. We will come back to this in the descriptions of FIGS. 2c and 8.

The repeated and time-varying stress exerted on the gasket 15 is generally the result of one or more external stresses γₑₓₜ exerted on the electronic board 1 itself. This external stress or stresses γₑₓₜ may be desired. This is the case, for example, when carrying out ageing or robustness tests on a part, such as an electronic board. Ageing or robustness tests aim to define the conditions that lead the part to damage. According to the prior art, while such tests allow to identify, even approximately, the conditions under which the damage to the part occurs and failure occurs, they do not allow to know, in advance, when this failure will occur, nor do they aim to prevent this failure. As will be seen in the following description, the present invention applies to this type of test.

More classically, the external stress or stresses γₑₓₜ is/are undesirable but not avoidable. This is the case, for example, when the part, in this case the electronic board 1, is in an on-board environment which is subject to this type of stress. The external stress or stresses may be a variation in temperature, tension, compression, bending, torsion, a rotational speed of a rotating turbomachine part or an acceleration. An on-board electronic board 1 of a turbomachine part of an aircraft is typically subject to such external stresses γₑₓₜ repeated and variable over time. In normal use, this electronic board 1 may moreover be subjected to external stresses γₑₓₜ.

In the context of the invention, and for the sake of simplification, the term “external stress γₑₓₜ” refers both to a single external stress γₑₓₜ or to the resultant of several external stresses γₑₓₜ. It is only important that this external stress γₑₓₜ is exerted on the electronic board 1.

As illustrated in FIG. 1, the estimation method 100 comprises a first step consisting of supplying the assembly, as previously described.

Prior to this step, it may be necessary to carry out 105 an assembly of the electronic component 10 on the printed circuit board 2. The type of assembly varies according to the type of electronic component 10 used. Some electronic components 10 are connected to the electronic board 1 without any additional material, in particular by using the metal or metals from which their tabs are made. In this case, the operation by which they are connected to the electronic board 1 is soldering, and the gasket is referred to as a soldering gasket 15. The soldering gasket may therefore simply consist of an interface between the electronic component 10 and the printed circuit board 2. Other electronic components 10 are connected to the electronic board 1 using materials in addition to those from which they are made. In this case, the operation by which they are connected to the electronic board 1 is soldering, and the gasket is referred to as a soldering gasket 15. Alternatively, the gasket 15 may be a conductive adhesive gasket. The invention applies equally to these three assembly variants. What is important is that the electronic component 10 is connected to the electronic board 1 by at least one gasket 15.

The electronic component 10 may be any electronic component 10 that is connected to the electronic board 1 by means of at least one gasket 15. A main distinction is made between the electronic components 10 having at least one characteristic electrical quantity which varies as a function of an external stress γₑₓₜ and electronic components 10 whose characteristic electrical quantity or quantities is independent of the external stress γₑₓₜ, i.e., having no characteristic electrical quantity which varies as a function of the external stress γₑₓₜ.

For example, the resistors, the capacitors, the inductors and many passive electronic components are electronic components 10 having at least one characteristic electrical quantity that varies as a function of an external stress γₑₓₜ. If the electronic component 10 is a capacitor, then the electrical quantity is the capacitance of the electronic component 10. If the electronic component 10 is an inductor, then the electrical quantity is the inductance of the electronic component 10. In contrast, Ball Grid Arrays (BGAs) and Thin Small Outline Packages (TSOP) are electronic components 10 that have no characteristic electrical quantities that vary as a function of the external stress γₑₓₜ.

In the context of the invention, the electronic component 10 may consist of an assembly of electronic sub-components. This assembly is called an “electronic component 10” and has a characteristic electrical quantity that may or may not vary as a function of the external stress γₑₓₜ exerted on the electronic board 1. This is the case, for example, with the Wheatstone bridge, which is used in one embodiment of the invention described later in this description.

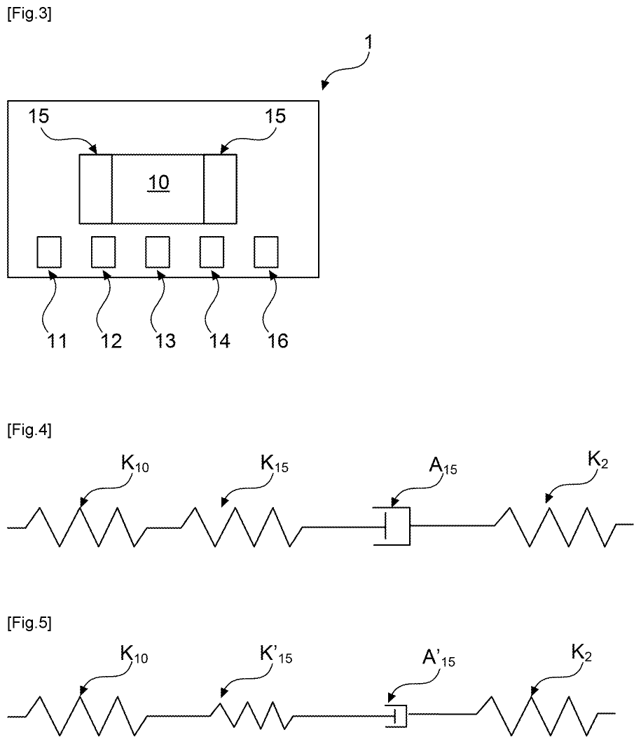

The electronic component 10 may be associated with secondary electronic components 11, 12, 13, 14, 16 which give it specific characteristics, for example allowing its output signal to be amplified, or which have another function useful for the specific implementation described (FIG. 3). In some embodiments, a thermistor 11 is used in conjunction with the electronic component 10 to determine the effect of temperature.

The printed circuit board 2 of the electronic board 1 is conventional and in some embodiments may comprise an internal component 20, located opposite the gasket 15, which has the characteristics of an electronic component 10 as previously described (FIG. 14).

At this stage, it should be noted that in the present description, “the element of the assembly” or “element” may refer to a body of the electronic component 10, a tab for attaching the electronic component 10 to the printed circuit board 2, the gasket 15 itself, a soldering pad, etc. In this way, the estimation of the level of damage to the element concerns any element of the assembly, or even elements located in the vicinity of said assembly.

The estimation method 100 also comprises a second step 120 consisting in voluntarily or involuntarily exerting an external stress γₑₓₜ, repeated and variable over time, on the electronic board 1 so as to generate an evolution in the viscoplastic behavior of the gasket 15. As may be seen from the above description, in the context of the invention, the external stress γₑₓₜ may be applied voluntarily, for example in the context of ageing or robustness tests, or it may be applied involuntarily, particularly in view of the environment wherein the electronic board 1 is located. In the latter case, the electronic board 1 is subjected to the external stress γₑₓₜ given the environment wherein it is located.

This external stress is exerted repeatedly and variably over time on the electronic board 1, generating a stress on both the electronic component 10 and the printed circuit board 2, and therefore generating a stress on the gasket 15. Given the viscoplastic behavior of the gasket 15, each time the external stress γₑₓₜ is exerted on the electronic board 1, this has the effect of generating a viscous relaxation of the gasket 15. In other words, after a characteristic time, called the relaxation time or time constant, this generates a change in the viscoplastic behavior of the gasket 15, which modifies the deformation rate of the electronic component 10 and the dimensions of the electronic component 10. This causes a change in the rate of change of the value of the electrical quantity or one of the characteristic quantities of this electronic component 10.

FIGS. 4 and 5 show schematically the behavior of the elements of the electronic board 1, respectively when the gasket 15 is new and when the gasket 15 is cracked after it has been subjected to repeated external stresses γext. The electronic component 10 and the printed circuit board 2 are represented schematically by springs of respective stiffness K10 and K2 because, being in the electronic board 1, they are also subject to the external stress γext. On the other hand, the gasket 15 is represented by a stiffness spring K15 coupled to a section damper A15 which represents the viscous damping supplied by the gasket 15, i.e., the ability of the gasket 15 to deform by stretching when subjected to external stress.

When the external stress γₑₓₜ is applied repeatedly and varies over time, the gasket 15 undergoes a non-instantaneous change in its viscoplastic behavior. The gasket 15 may then gradually crack over time to “absorb” this viscoplastic deformation. In this case, its resistant section gradually decreases over time, unlike those of the electronic component 10 and the printed circuit board 2, which do not crack. This viscoplastic deformation of the gasket 15 and the accompanying reduction in the resistant cross-section are represented by a reduction in the stiffness of the spring representing the gasket 15, which goes from the value K₁₅ in FIG. 4 to the value K′₁₅ in FIG. 5. At the same time, as the resistant cross-section of the gasket 15 becomes smaller and smaller, the viscous damping supplied by the gasket 15 decreases, resulting in a reduction in the cross-section of the damper from the value A₁₅ in FIG. 4 to the value A′₁₅ in FIG. 5.

In addition, during the change in the viscoplastic behavior of the gasket 15, as the viscous damping achieved by the gasket 15 decreases, the rate of change in the behavior of the gasket 15 increases and, at the same time, the rate of change in the electrical quantity of the electronic component 10 increases, as the electrical quantity of the component 10 changes as a function of the external stress γₑₓₜ. When the electrical quantity of the component 10 does not vary as a function of the external stress γₑₓₜ and does not allow the phenomenon of relaxation of the external stress γₑₓₜ by the gasket 15 to be accounted for, it is the rate of variation of the electrical quantity of the internal component 20 of the electronic board 1 that increases in parallel with the rate of deformation of the gasket 15 (FIG. 14). As we will see in more detail later, this phenomenon may be measured by estimating the time constant τ of the electrical quantity.

Of course, as mentioned earlier, other elements of the assembly may crack and therefore suffer a damage when the electronic board 1 is subjected to the external stress γext.

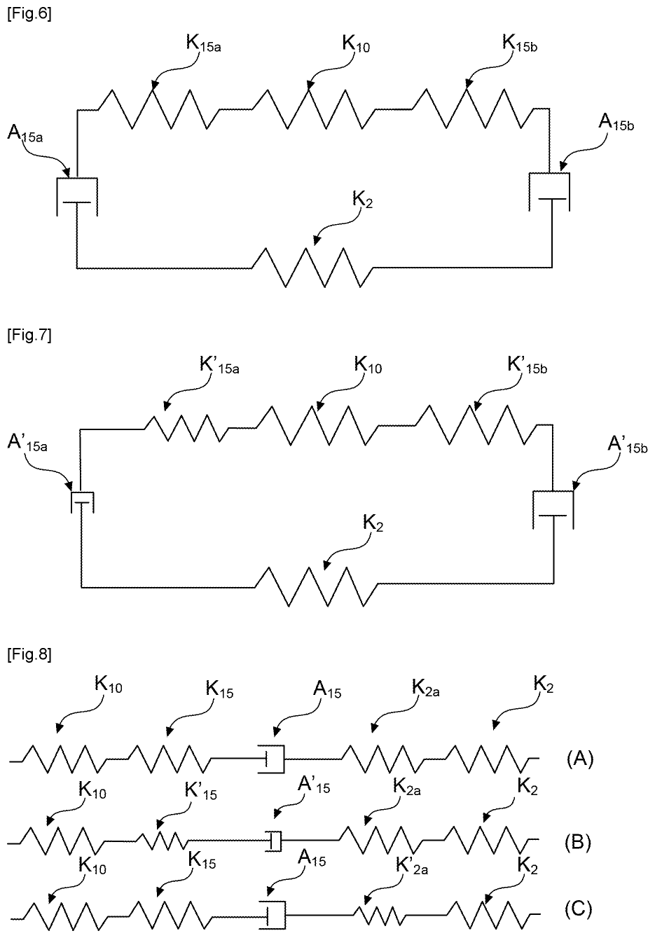

FIGS. 6 and 7 are complete schematic representations of the schematic representations shown in FIGS. 4 and 5 respectively. As most electronic components 10 are connected to the printed circuit board 2 by at least two gaskets 15, this shows the respective stiffnesses K₁₅ₐ and K_{15b} of the springs symbolizing each of the gaskets 15a, 15b and the viscous damping A₁₅ₐ, A_{15b} produced by each of the gaskets 15a, 15b. As schematically illustrated in FIG. 7 by means of springs of different stiffnesses K′₁₅ₐ and K′_{15b} (K′₁₅ₐ being symbolically smaller) and dampers of different cross-sections A′₁₅ₐ, A′_{15b} (A′₁₅ₐ being symbolically smaller), the gaskets 15a, 15b do not necessarily plastically deform in the same way and at the same rate in response to the voluntary or involuntary exertion 120 of the external stress γₑₓₜ. A first gasket 15a may therefore be quicker to undergo a viscoplastic deformation than a second gasket 15b connecting the electronic component 10 to the printed circuit board 2. In the example shown in FIG. 7, the gasket 15a cracks while the gasket 15b does not crack.

At this stage, it should be pointed out that other parts of the electronic board 1 are likely to crack under the effect of the external stress γₑₓₜ. Whichever the element cracks, its stiffness decreases as its resistant cross-section decreases. The other elements, whose stiffness has not changed, are therefore subjected to less and less strain, particularly the electronic component 10. In any case, whether it is the gasket 15 that cracks (e.g., FIG. 2b) or another element of the electronic board 1 (e.g., the soldering pad in FIG. 2c), the relaxation of the gasket 15 is less and less visible. The change in the variation of the electrical quantity is therefore similar in both cases.

FIG. 8 illustrates two different cases of cracking when a soldering pad 2a on the electronic board 1 is interposed between the gasket 15 and the printed circuit board 2. The principle is the same as that described above. Step A) illustrates the state of the assembly when it is new, while step B) illustrates the assembly when the gasket 15 cracks and step C) when the soldering pad 2a cracks.

Still with reference to FIG. 1, according to one aspect of the invention, the method 100 for estimating the level of damage to the element comprises a step 140 of estimating a time constant τ of the electrical quantity of the electronic component 10 or of an internal component 20 of the electronic board 1 located inside the printed circuit board 2 facing the gasket 15 between two instants t₀, t₁ during the modification of the viscoplastic behavior of the gasket 15. We will return to the embodiment wherein the estimated time constant τ is that of the electrical quantity of the internal component 20 in the description relating to FIG. 14.

As introduced in the preceding description, the time constant τ of the electrical quantity of the electronic component 10 accounts for the rate of change of the electrical quantity of the electronic component 10, and therefore for the rate of change of the deformation of the electronic component 10, and consequently for the phenomenon of relaxation of the external stress γₑₓₜ achieved by the gasket 15 when its viscoplastic behavior changes. Thus, the estimation of the time constant τ between the two instants t0 and t1 allows to estimate and characterize the relaxation dynamics of the external stress γₑₓₜ during the change in the viscoplastic behavior of the gasket 15, highlights a change in the stiffness or viscosity of the element of the assembly, and therefore a level of damage to the element of the assembly.

The estimation method 100 according to the invention comprises a step 150 of estimating the level of damage to the element of the assembly from the time constant τ previously estimated during step 140. Depending on the value of the time constant τ, it is possible to determine precisely the instants at which these changes of state occurred and their degree of impact on the evolution of the damage, and therefore the level of damage to the element of the assembly. This allows to reliably estimate the level of damage over the entire dynamic range of damage to the element of the assembly, and not just when the gasket 15 is almost completely damaged, as in the methods of the prior art.

For certain types of external stress γₑₓₜ, it may be particularly advantageous to monitor the evolution of the external stress γₑₓₜ as this improves the estimate 150 of the level of damage.

In this respect, with reference to FIG. 1, the estimation method 100 may comprise, concomitantly with the step 120 of exerting, voluntarily or involuntarily, the external stress γₑₓₜ, a step 125 consisting of determining the evolution of the external stress γₑₓₜ and/or an amplitude of a variation in the external stress γₑₓₜ while the external stress γₑₓₜ is exerted on the electronic board 1 and the gasket 15 deforms. This determination may therefore involve effectively measuring the characteristic parameters of the external stress γₑₓₜ. Having said that, if the external stress γₑₓₜ is imposed by the application of a setpoint, there is no measurement to be performed but simply a setpoint signal to be known. In either case, this allows to improve the estimate made during step 150 by correlating the evolution of the time constant τ with the evolution of the characteristic parameters of the external stress γₑₓₜ.

In practice, this is of particular interest when the estimation method 100 is implemented for ageing or robustness tests. Indeed, if, during the test, the external stress γₑₓₜ is exerted very quickly compared with the relaxation time of said external stress γₑₓₜ by the gasket 15 and the amplitude of this external stress γₑₓₜ is unknown, then the implementation of the step 125 of measuring the evolution of the external stress γₑₓₜ allows to improve the estimate 150 of the level of damage to the element of the assembly.

Similarly, still in the context of ageing or robustness tests, if the external stress γₑₓₜ is repeatable and variable over time, but the value of this external stress γₑₓₜ and its rate of change are not known, the estimate 140 of the time constant τ is sufficient to establish that changes in the rates of change of the electrical quantity are occurring and that damage is progressing. In this case, if the estimate 140 of the time constant τ allows to know that the level of damage currently measured is greater compared to a previously determined level of damage, the implementation of the step 125 of measuring the evolution of the external stress γₑₓₜ allows to better estimate, during step 150, this level of damage compared to the complete level of damage.

In this respect and according to a particular implementation, the step 150 of estimating the level of damage to the element of the assembly comprises a first sub-step 152 of representing the evolution of the time constant τ as a function of the evolution of the external stress γₑₓₜ and/or the amplitude of the variation of the external stress γₑₓₜ between two instants during the modification of the viscoplastic behavior of the gasket 15. In other words, in the first sub-step 152, a curve f(x)=y is plotted where x is a parameter measuring the external stress γₑₓₜ or a parameter measuring the amplitude of the variation in said external stress, and y is the time constant τ. The longer the analysis window, i.e., the time elapsing between the two instants, the more relevant the subsequent analysis. It is then possible to implement a second sub-step 154 to analyze the time constant τ between the two instants, and in a third sub-step 156 to deduce therefrom an improved estimate of a level of damage to the element of the assembly.

According to an alternative implementation, the step 150 of estimating the level of damage to the element of the assembly comprises a first sub-step 152′ of supplying an abacus representing the evolution of the time constant τ as a function of the duration and/or frequency of exertion and/or the amplitude of the variation in the external stress γₑₓₜ, or of supplying a database comprising predetermined values of the time constant τ as a function of the duration and/or frequency of exertion and/or the amplitude of the external stress γₑₓₜ. Then, in a second sub-step 154′, the time constant τ is compared with data from the abacus or the database in order to estimate, in a third sub-step 156′, a level of damage to the element.

This implementation is simpler than the previous one and allows to automate this step 150 the abacus or, as the case may be, the database, already comprises the data characterizing the evolution of the time constant τ as a function of the variations in the external stress γext. It may be possible to connect the electronic board 1 to a processor 2 configured to analyze and/or treat the aforementioned data. Again, it should be remembered that this implementation may be used in the case where the estimation of the level of damage is likely to be more accurate and therefore likely to be improved by a correlation of the evolution of the time constant τ with the evolution of the characteristic parameters of the external stress γext.

According to a first embodiment of the estimation method 100 according to the invention wherein the electrical quantity of the electronic component 10 varies as a function of the external stress γₑₓₜ, the time constant τ of the electrical quantity of the electronic component 10 is estimated during step 140. The fact that the electrical quantity of the electronic component 10 varies as a function of the external stress γₑₓₜ means that the electrical quantity of the electronic component 10 may be used to estimate the level of damage to the element.

In this context and still with reference to FIG. 1, the step 140 of estimating the time constant τ of the electrical quantity of the electronic component 10 may typically be preceded by a step 130 of measuring the electrical quantity of the electronic component 10, followed by one or more steps 132, 134 of treating the measurements made during the measurement step 130. We'll come back to this in the following. The measurement step 130 may advantageously be implemented concomitantly with the step 120 of exerting, voluntarily or involuntarily, the external stress γₑₓₜ on the electronic board 1.

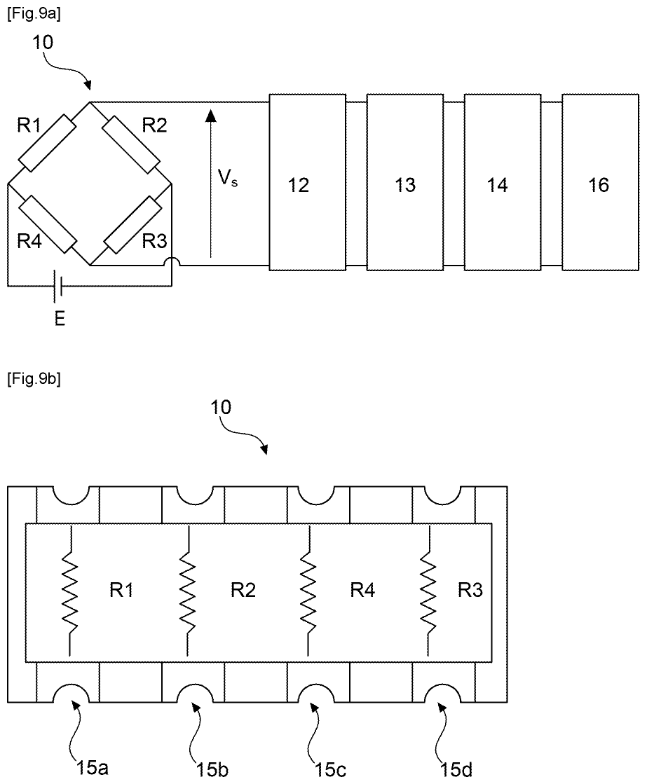

With reference to FIGS. 1 and 9a and according to a first example of application of the first embodiment, the electronic component 10 is a Wheatstone bridge comprising four resistors R1, R2, R4, R3, respectively connected to the printed circuit board 2 by a gasket 15a, 15b, 15c, 15d, and wherein the electrical quantity is an output voltage Vs of the Wheatstone bridge 10. The Wheatstone bridge 10 is a well-known assembly associated with measurable and easily controllable electrical quantities, which supplies a concrete and simple application of the present invention. It should be noted that the Wheatstone bridge 10 also has the advantage of eliminating the impact of the temperature coefficient on the resistors R1, R2, R4 and R3, since its characteristic electrical quantity is the output voltage Vs.

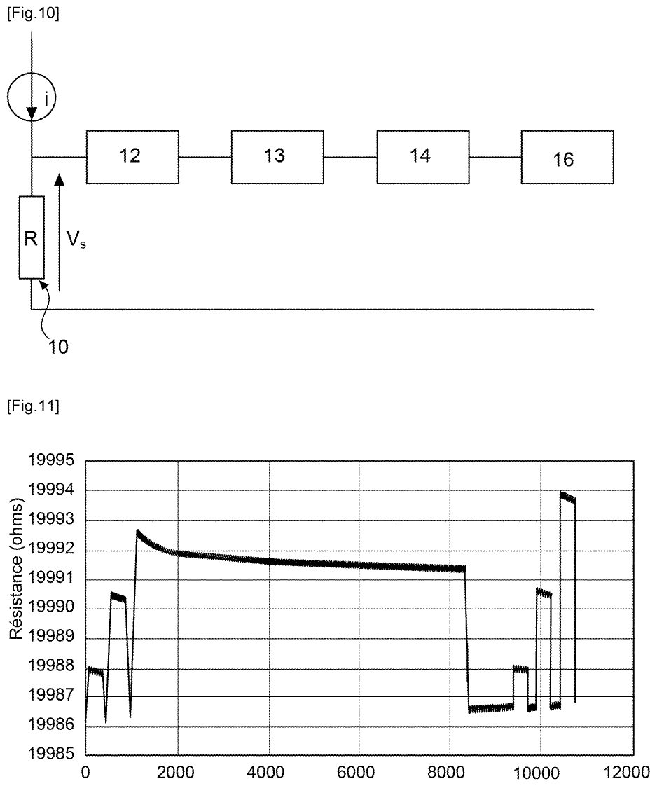

In an optional preliminary step 105, the Wheatstone bridge 10 is assembled on the electronic board 1 by attaching the resistors R1, R2, R4, R3 forming the Wheatstone bridge 10 by soldering. The gaskets 15a, 15b, 15c and 15d are therefore soldered gaskets. The Wheatstone bridge 10 is subjected to a supply voltage E and has an output voltage, denoted Vs in FIGS. 9a and 10.

According to a particular implementation illustrated in FIG. 9b, the four resistors R1, R2, R4, R3 of the Wheatstone Bridge 10 belong to the same resistor network. In practice, the four resistors R1, R2, R4 and R3 are therefore mounted on the same housing. Incidentally, the four resistors R1, R2, R4, R3 are made by the same manufacturer, are of the same technology, have substantially identical values and substantially identical resistance values as a function of temperature. Two resistors R1 and R3 of the four resistors R1, R2, R4, R3 are located in the corners and two other resistors R2 and R4 of the four resistors R1, R2, R4, R3 are located in the center. It is also advantageous to have low-precision resistors R1, R2, R4, R3, as resistors which are both very precise and have very low temperature coefficients would make it difficult to observe the relaxation of the external stress by the gaskets 15a, 15b, 15c and 15d.

Alternatively, the four electrical resistors R1, R2, R4, R3 may be located on separate housings, each housing having two terminations. In this case, it is advantageous if the four resistors R1, R2, R4, R3 have the same value, the same technology and are made by the same manufacturer. Advantageously, they therefore have substantially identical values and substantially identical resistance values as a function of temperature and one of the four resistors has a gasket 15a, 15b, 15c or 15d which has been deliberately weakened.

According to another variant, although the four resistors R1, R2, R4 and R3 have substantially identical values and substantially identical resistance values as a function of temperature, they are made by different manufacturers and/or are of different technology and the gaskets 15a, 15b, 15c and 15d are made without seeking to deliberately weaken any one of them.

It is possible to add a thermistor 11 to the electronic board 1, in particular near the resistors R1, R2, R4, R3 of the Wheatstone bridge 10, to monitor the temperature evolution. It is possible to add a filter 12 allowing to reduce the noise of the output voltage Vs, an amplifier stage 13 to amplify the output voltage Vs and facilitate the subsequent estimation of the time constant, an analogue-to-digital converter 14 to transform the output voltage Vs into a digital signal, or a digital signal processor 16 to perform signal treating on the digital signal obtained by the analogue-to-digital converter 14.

The electronic board 1 thus assembled is then supplied 110 to implement the method 100 for estimating the level of damage according to the invention. The Wheatstone bridge 10 may then be supplied with a voltage E if this is not already the case. It should be noted that when the Wheatstone bridge 10 has not been subjected to any stress- and is therefore new- and the gaskets 15 have not yet cracked, all the phenomena compensate each other, i.e., the variations in resistance due to the temperature coefficients of the resistors R1, R2, R4 and R3, the variations in resistance due to the relaxation of the gaskets 15, and the variations in resistance due to the relaxation of the electronic board 1. Consequently, at t=t0, all resistors R1, R2, R4 and R3 have the same value and the output voltage Vs is therefore close to 0. Interestingly, the inventors of the present invention have found that, when the Wheatstone bridge 10 is subjected to a repeated and variable external stress γₑₓₜ, it is the gaskets 15 of the resistors R1 and R3 located at the corners that undergo a viscoplastic deformation and begin to crack before the gaskets 15 of the resistors R2 and R4 located in the center because of their position on the Wheatstone bridge 10. This is because the resistors R1 and R3 are subject to greater differences in elongation during expansion or mechanical deformation.

During a step 120, an external stress γₑₓₜ, repeated and variable over time, is exerted on the electronic board 1. In the present embodiment, this external stress γₑₓₜ is temperature.

Typically, a measurement 130 or a recording 130 of the output voltage Vs of the Wheatstone bridge 10 may be performed in parallel with the step 120 during which the external stress γₑₓₜ, namely the temperature, is exerted on the electronic board 1. This allows to follow the evolution of the output voltage Vs at least from the moment when the external stress γₑₓₜ begins to be exerted until the viscoplastic deformation of the gaskets 15 of the corners. A first treating step 132 may then be carried out, consisting of filtering the output voltage signal Vs to remove the noise. In this respect, the voltage Vs may be filtered at a sampling frequency of between 5 seconds and 120 seconds, depending on the intended application. Preferably, the sampling frequency is faster than the time constant, and even more preferably at least 20 times faster.

In step 140, the time constant τ of the output voltage Vs, and more precisely of the digital signal corresponding to the output voltage Vs, is estimated. In this respect, for example, the time constant τ may be estimated from the delay between the curve representing the evolution of the temperature γₑₓₜ (e.g., in ° C.) as a function of time and the curve representing the evolution of the output voltage Vs as a function of time. This gives the relaxation time of the gasket or gaskets 15 when cracking. However, it is also possible to estimate the time constant τ of the output voltage Vs using an algorithm such as least squares.

The level of damage 150 may then be estimated using the specific implementations described above. It is possible either to record 152 the evolution of the time constant τ as a function of the evolution of the temperature γₑₓₜ and/or of the amplitude of the variation in temperature γₑₓₜ between two instants during the modification of the viscoplastic behavior of the gasket 15 or to use 152′ an abacus representing the evolution of the time constant τ as a function of the temperature γₑₓₜ and/or of the amplitude of the variation in temperature γₑₓₜ or to use 152′ a database comprising predetermined values of the time constant τ as a function of the temperature γₑₓₜ and/or of the amplitude of the temperature variation γₑₓₜ. Then, depending on the case, it is necessary to analyze 154 the evolution of the time constant τ between the two instants considered or to compare 154′ the time constant τ with data from the abacus or from the database in order to estimate 156, 156′ a level of damage to the gasket or gaskets 15.

It should be noted that the Wheatstone bridge 10 of this application example of the first embodiment may be used beforehand to determine abacuses allowing the implementation of step 150 as previously mentioned. In fact, the external stress γₑₓₜ is the temperature and the change in the viscoplastic behavior of the gasket 15 and the relaxation of this stress by the gasket 15 depends on the temperature.

This estimate supplies a factual assessment of the damage undergone by the gaskets 15 in the corners of the Wheatstone bridge 10. If this damage is due to temperature variations and the difference in the coefficient of expansion between the Wheatstone bridge 10 and the printed circuit board 2 on which it is mounted, then the evolution of the damage to the Wheatstone bridge 10 allows to estimate the damage to the other components of the board which are subject to the same phenomenon. It is also possible to compare the damage between different boards with different temperature profiles or printed circuit boards with different coefficients of expansion.

With reference to FIGS. 1 and 10 and according to a second example of application of the first embodiment, the electronic component 10 is a resistor, and the electrical quantity is the resistor R of the electronic component 10.

The estimation method 100 according to this second application example may comprise an optional preliminary step 105, wherein the resistor 10 is mounted on the electronic board 1 by attaching it to the printed circuit board 2 by soldering so as to form a soldering gasket 15. Such a resistor 10 is a control component because it is only used for the purposes of the method 100 for estimating the damage to the element, the element imaging the general state of the other elements of the electronic board 1. This being said, as an alternative, the resistor 10 may also be a resistor already present on the electronic board 2 without prejudice to the invention.

As seen in the Wheatstone bridge 10 embodiment, it is also possible to add to the electronic board a thermistor 11 allowing to monitor the temperature evolution in the vicinity of the resistor 10, a filter 12 to reduce the noise of the resistor, an analogue-to-digital converter 14 to transform the measurement of the resistance R into a digital signal and a digital signal processor 16. The electronic board 1 thus assembled is then supplied 110 to implement the method 100 for estimating the level of damage according to the invention. At the same time, power is supplied to the electronic board 1 if it is not already powered.

During a step 120, an external stress γₑₓₜ, repeated and variable over time, is exerted on the electronic board 1. In the present embodiment, this external stress γₑₓₜ is the temperature variation.

Typically, the resistance R may be measured or recorded 130 in parallel with the step 120 during which the electronic board 1 is subjected to the external stress γₑₓₜ. This allows to follow the evolution of the resistance R at least from the moment when the external stress γₑₓₜ begins to be exerted until the change in the viscoplastic behavior of the gasket 15. Preferably, the estimation method 100 then comprises a first treating step 132 consisting of filtering the signal from the resistor R to remove the noise.

Advantageously, the estimation method 100 comprises, after the first treating step 132, a second treating step 134 consisting in removing the impact of the temperature from the value of the resistance R. Unlike the Wheatstone bridge embodiment, it is the value of the resistance R that is used. As you know, the value of resistance (an electrical quantity) varies as a function of temperature. This known phenomenon is evaluated by the temperature coefficient of the resistor. It is therefore advisable to remove the impact of temperature from the resistance R so as not to measure this variation in the resistance R as a function of temperature, since this is not the phenomenon that needs to be characterized.

In this respect and also advantageously, it should be specified that, prior to the step 105 of assembling the resistor 10 on the electronic board 1, the estimation method 100 may also comprise a step (not illustrated) of determining a reference resistance R_{ref} of the resistor 10 as a function of the temperature γₑₓₜ when said resistor 10 is disjoined from the electronic board 1. This allows the effects of temperature γₑₓₜ to be subtracted before the time constant is estimated when, as is the case here, the electrical quantity is intrinsically dependent on temperature γₑₓₜ. It should be noted that this may be generalized to any type of external stress γₑₓₜ.

At the end of the second treating step 134, a corrected resistance R′ is obtained, taking into account the subtraction of the extrinsic effect of temperature on the resistance R.

This being said, and even more advantageously, the resistor 10 may be a metal foil resistor. This type of resistor 10 is very stable at temperature, i.e., its resistance R is not very temperature-dependent, which means that there are no variations in the resistance R due to the impact of temperature.

In step 140, the time constant τ of the resistor R, and more precisely of the digital signal corresponding to the resistor R, is estimated, and then in step 150 the level of damage to the element is estimated from the previously determined time constant. These steps 140 and 150 are similar to those described previously in relation to the first application example of the first relative embodiment using the Wheatstone bridge. FIG. 11 illustrates the evolution of the time constant τ in the case of such an application example.

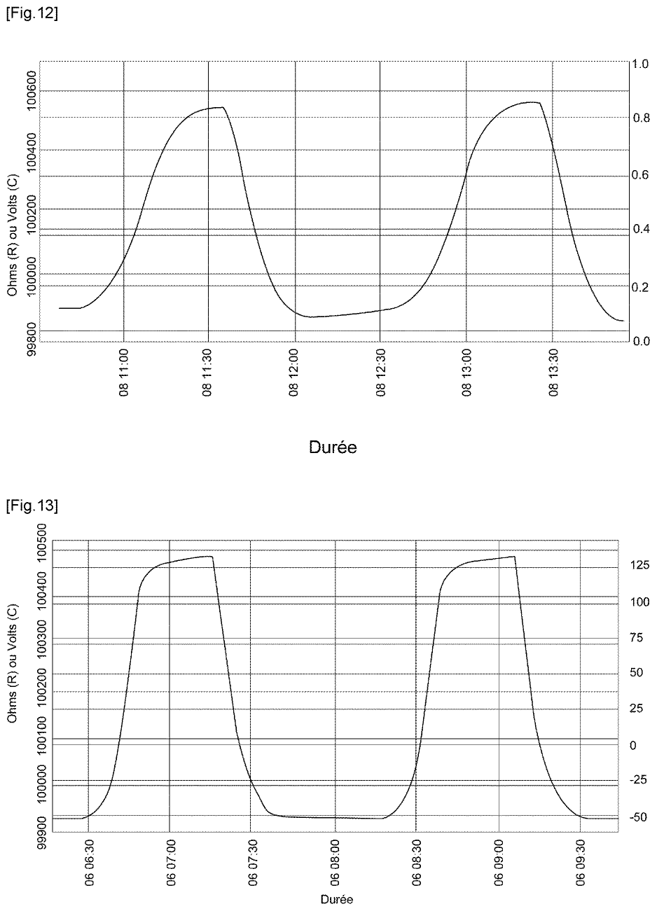

According to a variant of embodiment of the second application example, the electronic component 10 comprises several resistors arranged in parallel or in series. The electrical quantity is the resulting or equivalent resistance R. This variant of embodiment allows to average the progress of cracks, which vary greatly from one resistance R to another, and to better assess the evolution of average cracking. FIGS. 12 and 13 illustrate the evolution of the resultant or equivalent resistance R as a function of time for an assembly of ten ceramic resistors 10 R0402 of 1 Mohm in parallel on an electronic board 1, respectively, before and after modification of the viscoplastic behavior of the gasket or gaskets 15. The external stress γₑₓₜ is the temperature.

As shown in FIG. 12, the value of the resistance varies as a function of temperature and to subtract the effect of temperature, a subtraction step as described above is applied. Although the temperature is not shown in FIG. 12, it varies more rapidly than the resistance R. The temperature variations are “square”. When a crack appears in one of the gaskets 15, the stiffness of the cracked gasket 15 varies as its dimensions change. The balance of the mainlining of the different elements of the assembly, i.e., the resistors 10, the printed circuit board 2 and the electronic board 1, is therefore different. As the relaxation dynamics are also different, the larger the crack, the less mechanical resistance to deformation the gasket 15 offers. As the crack progresses, the time constant decreases, as shown in FIG. 13. By the time the crack is complete, the time constant τ is zero or close to zero.

FIG. 13 shows the relaxation of the same resistances after 4600 cycles of temperature variation, which resulted in a crack in the gasket 15. The difference between the curves in FIG. 12 and FIG. 13 is that, in FIG. 13, as the cracks are more advanced, the curve is more “square”. The variations in the resulting resistance R are temporally closer to variations in temperature. This is because the gasket 15 relaxes more quickly when the crack and therefore the damage has progressed. The gasket 15 therefore offers less resistance to deformation. To assess the remaining service life of the electronic board 1 as a whole, we may evaluate the delay between the temperature and the variation in the resulting resistance R, which allows to estimate the time constant τ. As the relaxation time constant τ decreases, the remaining service life of the electronic board decreases. The cracking is complete when the time constant τ is zero or almost zero.

According to a third example of application of the first embodiment of the estimation method 100 according to the invention, wherein the electrical quantity is the capacitance, the electronic component 10 is formed by an RC circuit, namely a circuit comprising a resistor and at least one capacitor connected in series or in parallel. In this case, an alternating current is passed through the RC circuit and the voltage at the terminals of the resistor is measured. In a first variant of embodiment, the RC circuit comprises a single capacitor. In a second variant of embodiment, the RC circuit comprises a plurality of capacitors arranged in parallel or in series. This variant of embodiment allows to average the progress of cracks, which varies greatly from one capacity to another, and to better assess the evolution of average cracking.

According to a fourth example of application of the first embodiment of the estimation method 100 according to the invention, wherein the electrical quantity is the capacitance, the electronic component 10 is formed by a Sauty-Wien bridge. The operating principle is similar to that of the Wheatstone bridge, but with an electronic component 10 comprising two capacitors and two resistors. In a particular implementation, the Sauty-Wien bridge comprises two identical resistors and two identical capacitors, one of which comprises a deliberately weakened gasket 15.

According to a fifth example of application of the first embodiment of the estimation method 100 according to the invention, wherein the electrical quantity is the inductance, the electronic component 10 is formed by a RL circuit, namely a circuit comprising a resistor and at least one inductor connected in series or in parallel. In this case, an alternating current is passed and the voltage at the terminals of the resistor is measured. In a first variant of embodiment, the RL circuit comprises a single inductor. In a second variant of embodiment, the RC circuit comprises a plurality of inductors arranged in parallel or in series. This variant of embodiment allows to average the progress of cracks, which vary greatly from one inductor to another, and to better assess the evolution of average cracking.

According to a second embodiment of the estimation method 100 according to the invention wherein the electrical quantity of the electronic component 10 is independent of the external stress γₑₓₜ, the time constant τ of the electrical quantity of the internal component 20 of the printed circuit board 2 is estimated during step 140 (FIG. 14). The fact that the electrical quantity of the electronic component 10 is independent of the external stress γₑₓₜ, and therefore does not vary as a function of the external stress γₑₓₜ, means that the electrical quantity of the electronic component 10 may not be used to estimate the level of damage to the element of the assembly. The internal component 20 is therefore used to make such an estimate.

According to an example of application of this second embodiment, the internal component 20 is a resistor. In the example of embodiment shown, the electronic component 10 comprises a ball array. It is soldered to the printed circuit board 2 of the electronic board 1 by means of a soldering gasket 15 in the form of a ball.

The internal component 20 is located inside the electronic board 1, and more specifically inside the printed circuit board 2 opposite the gasket 15, so that it is able to account for the change in the viscoplastic behavior of the gasket 15 in the event of damage to the assembly element. The internal component 20 is used in the same way as the electronic component 10 in the embodiments described above and is used to estimate the time constant associated with the relaxation of the gasket 15.

According to a particular implementation illustrated in FIG. 14, the internal component 20 is a resistive element. Although it is common practice to use resistive elements as internal components in the electronic boards, this embodiment is by no means limited to the use of the resistive element. The method 100 for estimating damage described in the example of embodiment shown in FIG. 10 may be used in the same way for this application.

Advantageously, the internal component 20 is made of constantan. The constantan has a resistivity dependent very little on temperature, so when the external stress γₑₓₜ exerted or subjected is the temperature, there is no need for the step of subtracting the impact of temperature on the resistivity value. Constantan, which is also used in strain gauges, is therefore particularly advantageous.

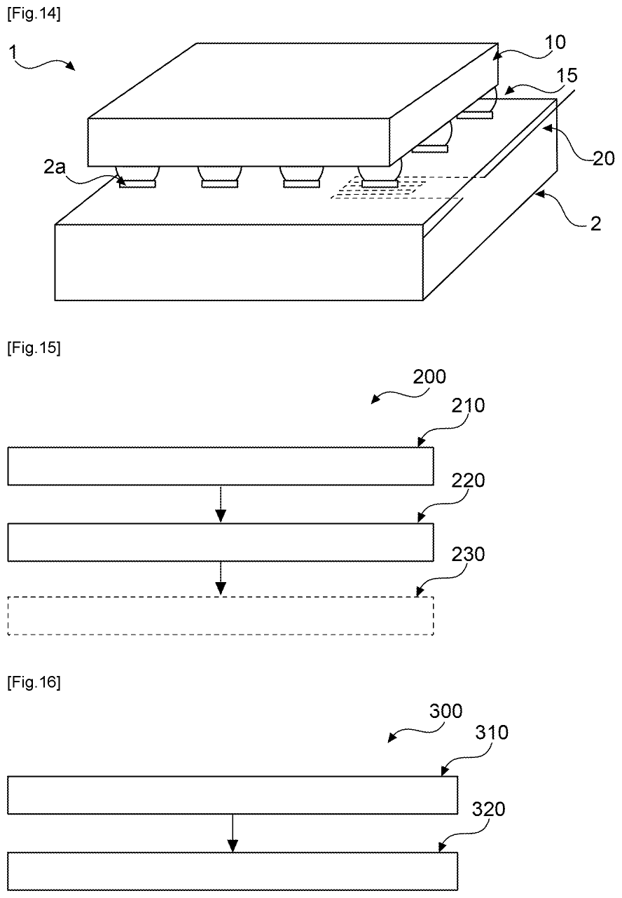

With reference to FIG. 15, the invention also relates to a method 200 for monitoring the evolution of damage comprising the steps described below.

In a first step 210, a method 100 for estimating the level of damage to a gasket 15 as previously described is implemented.

In a second step 220, the step 140 of estimating the time constant τ and the step 150 of estimating the level of damage of the element are repeated successively several times during the modification of the viscoplastic behavior of the gasket 15.

The method 200 therefore differs from the method 100 for estimating a level of damage in that it repeats steps 140 and 150 several times, which allows to monitor the evolution in damage over time.

The fact that the external stress γₑₓₜ is exerted on the electronic board 1 for a long period of time makes this monitoring possible. The monitoring may be carried out continuously or discontinuously over several hours, months or years to track the progress of damage and identify the exact moment when damage is complete.

The method 200 for monitoring the evolution of the damage may therefore comprise a step 230 consisting of analyzing the time constants measured during steps 210 and 220 to deduce the exact moment when the damage is complete.

With reference to FIG. 16, the invention also relates to a method 300 for maintaining predictively an electronic board 1 comprising the steps mentioned below.

In a first step 310, the method 100 for estimating the level of damage to a gasket 15 as described above or the method 200 for monitoring damage as described above is used.

In a second step 320, a predictive maintenance of the electronic board 1 is carried out according to the level of damage estimated at the end of the estimation step 150 or a last estimation step 150, as the case may be.

It may be advantageous to implement the maintenance method 300 according to the invention as soon as the estimated time constant indicates a level of damage greater than or equal to 40%, preferably greater than or equal to 60%. This allows a high margin to be taken and avoids failures of the electronic board 1 in operation, while avoiding a reduction in the operational availability of the electronic board 1 and the resulting increase in costs.

The configurations shown in the figures are only possible examples, and by no means limitative, of the invention which, on the contrary, encompasses all the design variants available to a person skilled in the art.

1. A method for estimating the level of damage to an element of an assembly, the assembly comprising:
an electronic component,
an electronic board comprising a printed circuit board, and
at least one gasket having viscoplastic behavior made between the printed circuit board and the electronic component,
the estimation method comprising the following steps:
supplying the assembly,
voluntarily or involuntarily exerting an external stress (γₑₓₜ), repeated and variable over time, on the electronic board so as to generate a change in the viscoplastic behavior of the gasket,
estimating a time constant (τ) of an electrical quantity of the electronic component or of an internal component of the electronic board located inside the printed circuit board and opposite the gasket between two instants (t₀, t₁) during the modification of the viscoplastic behavior of the gasket,
estimating a level of damage of the element from the previously estimated time constant (τ).

2. The estimation method according to claim 1, comprising, concomitantly with the step of exerting, voluntarily or involuntarily, the external stress (γₑₓₜ), a step including determining an evolution in the external stress (γₑₓₜ) and/or an amplitude of a variation in the external stress (γₑₓₜ) during the exertion, voluntary or involuntary, of the external stress (γₑₓₜ) and the modification of the viscoplastic behavior of the gasket.

3. The estimation method according to claim 1, wherein the step of estimating the level of damage to the element comprises the following sub-steps:
recording the evolution of the time constant (τ) as a function of the evolution of the external stress (γₑₓₜ) and/or of the amplitude of the variation of the external stress (γₑₓₜ) between two instants during the viscoplastic deformation of the gasket,
analyzing the evolution of the time constant (τ) between the two instants,
estimating the level of damage to the element.

4. The estimation method according to claim 1, wherein the step of estimating the level of damage to the element comprises the following sub-steps:
supplying an abacus representing the evolution of the time constant (τ) as a function of the duration and/or frequency of exertion and/or the amplitude of the variation in the external stress (γₑₓₜ), or supplying a database comprising predetermined values of the time constant (τ) as a function of the duration and/or frequency of exertion and/or the amplitude of the external stress (γₑₓₜ),
comparing the time constant (τ) with data from the abacus or from the database,
estimating a level of damage to the element.

5. The estimation method according to claim 1, wherein the electrical quantity of the electronic component varies as a function of the external stress (γₑₓₜ), and wherein, during the estimating the time constant (τ) step, the time constant (τ) of the electrical quantity of the electronic component is estimated.

6. The estimation method according to claim 5, further comprising, before the step of estimating the time constant (τ), the following steps:
measuring the electrical quantity of the electronic component,
treating the measurements made during the measurement step.

7. The estimation method according to claim 5, wherein the electronic component is a Wheatstone bridge.

8. The estimation method according to claim 7, wherein the Wheatstone bridge is formed by four resistors, each resistor being connected to the printed circuit board by a gasket, the electrical quantity being an output voltage (Vs) of the Wheatstone bridge.

9. The estimation method according to claim 5, wherein the electronic component is a resistor, and wherein the electrical quantity is the resistance of the electronic component.

10. The estimation method according to claim 9, wherein the electronic component is a metal foil resistor.

11. The estimation method according to claim 1, wherein the electrical quantity of the electronic component is independent of the external stress (γₑₓₜ), and wherein, during the estimating a time constant (τ) step, the time constant (τ) of the internal component is estimated.

12. The estimation method according to claim 1, wherein the external stress (γₑₓₜ) is a temperature variation, a tension, a compression, a bending, a torsion, a rotational speed of a rotating turbomachine part or an acceleration.

13. The method according to claim 1, wherein the element is a body of the electronic component, a tab for attaching the electronic component to the printed circuit board, the gasket or a soldering pad (2a) interposed between the gasket and the printed circuit board.

14. A method for monitoring the evolution of damage comprising the following steps:
implementing a method for estimating the level of damage to an element of the assembly according to claim 1,
successively repeating the step of estimating the time constant (τ) and the step of estimating the level of damage to the element several times during the viscoplastic deformation of the gasket.

15. A method for maintaining predictively an electronic board comprising the following steps:
implementing a method for estimating the level of damage to an element of an assembly according to claim 1,
carrying out a predictive maintenance on the electronic board according to the level of damage estimated at the end of the estimation step of estimating the level of damage to the element several times or a last estimation step of estimating the level of damage to the element.

16. A method for maintaining predictively an electronic board comprising the following steps:
implementing a method for estimating the level of damage to an element of an assembly according to a monitoring method according to claim 14,
carrying out a predictive maintenance on the electronic board according to the level of damage estimated at the end of the estimation step of estimating the level of damage to the element several times or a last estimation step of estimating the level of damage to the element.
